(19) United States
(12) Patent Application Publication
(10) Pub. No.: US 2011/0176082 A1
(43) Pub. Date: Jul. 21, 2011

(54) Mounting Members For Touch Sensitive Displays

(76) Inventors: Matthew Allard, Skudai (MY); John David Newton, Auckland (NZ); Simon James Bridger, Auckland (NZ)

(21) Appl. No.: 13/008,678

(22) Filed: Jan. 18, 2011

(30) Foreign Application Priority Data
Jan. 18, 2010 (AU) 2010900160

(51) Int. Cl. G02F 1/1333; H05K 5/02; H05K 7/02

(52) U.S. Cl. 349/58; 361/752; 361/809

(57) ABSTRACT

A mounting assembly for an optical touch system can comprise an elongated member defining a top face extending in a plane. A first mounting portion extends perpendicular to a first end of the elongated member and a second mounting portion extends perpendicular a second end. The elongated member defines a first side face perpendicular to a top face and each mounting portion defines a second side face perpendicular to the top face. The mounting assembly is directly mounted to a panel with the top face of the elongated member overlaying at least a portion of the front face of the panel, the first side face overlaying at least a portion of the top edge, the top face of each mounting portion overlaying at least a portion of the front face along the side edges, and each second side face overlaying at least a portion of a respective side edge.

### CROSS-REFERENCE TO RELATED APPLICATIONS

This application claims priority to Australian Provisional Application No. 2010900160, filed Jan. 18, 2010 by Matthew Allard, and entitled “An Optical Touch Sensitive Display Comprising a Sensor Mounting Member,” which is incorporated by reference herein in its entirety.

### BACKGROUND

Touch-enabled computing devices continue to increase in popularity. Such systems typically use one or more sensors, such as line scan or area cameras, to image an area that includes the top of a display, such as a liquid crystal diode (LCD) panel. For example, a touch-enabled display will utilize the display, along with the requisite sensor(s) and other optical hardware.

Various techniques are used to assemble touch-enabled displays. For example, sensors may be attached to an overlay, such as a sheet of glass, plastic, or some other transparent material. The overlay can then be positioned over the display device.

### SUMMARY

A mounting assembly as discussed herein can be used to provide an improved touch-enabled display. The mounting assembly can comprise an elongated member defining a top face extending in a plane, with the elongated member extending in a first direction. A first mounting portion extends perpendicular to a first end of the elongated member and a second mounting portion extends perpendicular to a second end of the elongated member. The elongated member may be fixed in length or may be extendible in the first direction.

The elongated member further defines a first side face perpendicular to the top face and each of the plurality of mounting portions further defines a second side face perpendicular to the top face. The mounting assembly can be directly mounted to a panel (such as an LCD panel) defining a front face, a top edge perpendicular to the front face, and side edges perpendicular to the front face and the top edge. The mounting assembly can be positioned with the top face of the elongated member overlaying at least a portion of the front face of the panel, the first side face overlaying at least a portion of the top edge, the top face of each mounting portion overlaying at least a portion of the front face along the side edges, and each of the second side faces overlaying at least a portion of a respective side edge.

The panel can, of course, comprise a display device. For example, the front face of the LCD display can comprise the LCD sandwich structure itself or a cover or frame of the LCD. The display device can further comprise an LCD bezel which locates over the mounting assembly so that the mounting assembly is positioned between the front face of the LCD and the LCD bezel.

In some implementations, the mounting assembly comprises a plurality of sensor receiving portions, each sensor receiving portion located at a junction between the elongated member and the mounting portion, each sensor receiving portion shaped to receive a sensor. As one example, each sensor receiving portion may define a recess in the top face. In one embodiment, a sensor is positioned at at least one of the sensor receiving portions, and a circuit board is connected to the sensor and mounted to the side face.

These illustrative embodiments are mentioned not to limit or define the limits of the present subject matter, but to provide examples to aid understanding thereof. Illustrative embodiments are discussed in the Detailed Description, and further description is provided there. Advantages offered by various embodiments may be further understood by examining this specification and/or by practicing one or more embodiments of the claimed subject matter.

### BRIEF DESCRIPTION OF THE DRAWINGS

FIG. 1 is an isometric view of a mounting assembly.

FIG. 2 is a view of the mounting assembly of FIG. 1.

FIG. 3 shows the mounting assembly of FIGS. 1-2 mounted on a panel.

FIGS. 4-5 are detail views of the mounting assembly mounted to the panel as shown in FIG. 3.

FIG. 6 shows a completed touch-enabled display device.

### DETAILED DESCRIPTION

Reference will now be made in detail to various and alternative exemplary embodiments and to the accompanying drawings. Each example is provided by way of explanation, and not as a limitation. It will be apparent to those skilled in the art that modifications and variations can be made. For instance, features illustrated or described as part of one embodiment may be used on another embodiment to yield a still further embodiment. Thus, it is intended that this disclosure includes modifications and variations as come within the scope of the appended claims and their equivalents.

In the following detailed description, numerous specific details are set forth to provide a thorough understanding of the claimed subject matter. However, it will be understood by those skilled in the art that claimed subject matter may be practiced without these specific details. In other instances, methods, apparatuses or systems that would be known by one of ordinary skill have not been described in detail so as not to obscure the claimed subject matter.

As noted above, certain optical touch systems can use components located on a transparent cover which is over a display. Typically this transparent cover is glass, but could also be plastic or a similar material. The addition of an optical touch system therefore adversely affects the overall height of the display. This can result in an undesirable appearance, and functionality may be impacted as well. For example, around 8% of light from the display can be lost when glass covers a display.

Additionally, such an optical touch system is often added to a display after the display has been manufactured, and usually such a touch system uses additional processing/electronics. When attaching a transparent cover to the front of a display there is a very high chance of dust particles being trapped between the transparent cover and the display, and so the attachment process must be performed in a clean room environment.

Presently-disclosed embodiments can address one or more of the foregoing issues. By using a mounting assembly 10 as discussed herein, an improved touch-enabled display can be provided. The optical touch system can be integrated with the display at the time of manufacture and does not require any external processing structures or the complexity of a clean room assembly processes. Additionally, use of mounting assembly 10 allows the optical touch system components to be used without a glass or other cover, resulting in improved display performance and a reduction in overall height for a more pleasing appearance.

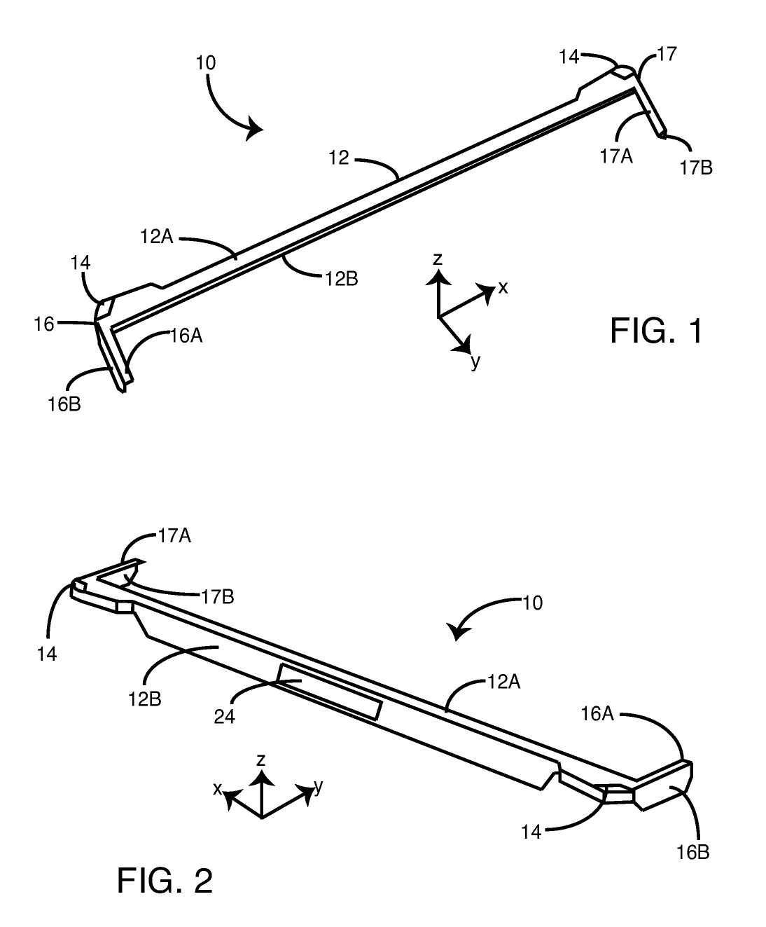

FIGS. 1-2 each depict a mounting assembly 10 configured according to the present subject matter. In this example, mounting assembly 10 includes an elongated member 12 extending in a first direction (the x-direction in this example) in a plane (the x-y plane in this example). Mounting assembly 10 features sensor receiving portions 14 at either end of the elongated member 12. Additionally, first mounting portion 16 and second mounting portion 17 extend perpendicular from first and second ends of elongated member 12. For example, the sensor receiving portions 14 may be formed as recesses at the junction between elongated member 12 and mounting portions 16, 17.

Elongated member 12 defines a top face 12A in the plane and first side face 12B perpendicular to top face 12A. In this example, top face 12A is generally in the x-y plane while first side face 12B is in the x-z plane. Each of the mounting portions 16, 17 defines a second side face (16B, 17B) that is also perpendicular to the top face. Thus, in this example, second side faces 16B and 17B each extend in the y-z plane. Generally, the second side faces are perpendicular to the first side face, though as shown here the side faces do not necessarily extend to meet the first side face. Mounting portions 16 and 17 also continue the top face, as shown at 16A and 17A, though faces 16A and 17A need not be co-planar with 12A.

Of course, no surface need be perfectly planar or perpendicular to another surface, and acceptable manufacturing tolerances will suffice. As another example, the angle between the top and side faces may be adjusted to allow for some degree of play, or even could be varied to accommodate placement on a panel that is not of a rectangular cross-section.

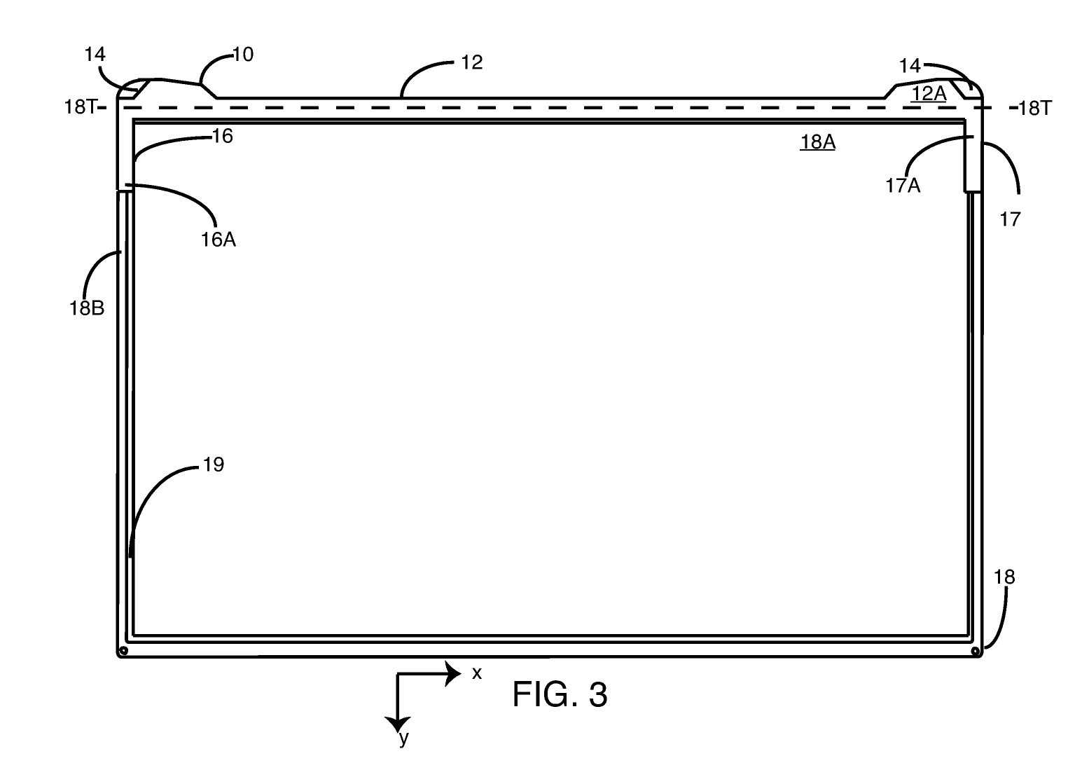

FIG. 3 shows mounting assembly 10 mounted to a panel 18. In this example, panel 18 defines a front face 18A, a top edge 18T perpendicular to front face 18A, and side edges 18B perpendicular to front face 18A and the top edge. Because FIG. 3 shows a view looking down on front face 18A, the location of the top edge is shown by the dashed line 18T. As can be seen in FIG. 3, mounting assembly 10 is positioned with top face 12A of elongated member 12 overlaying at least a portion of front face 18A of panel 18. Specifically, a portion of front face 18A near the top edge 18T is overlain, and as can be inferred from the positioning of mounting assembly 10, first side face 12B overlays at last a portion of the top edge. Additionally, a top face (16A, 17A) of each mounting portion (16, 17) overlays at least a portion of front face 18A and side edges 18B of panel 18.

In this example, panel 18 comprises a display device, for example an LCD display, plasma display, organic light emitting diode (OLED), or another substantially planar surface. The top and side edges of panel 18 may be at least partially defined by a frame structure 19. For example, frame structure 19 may be used to secure the LCD sandwich structure during manufacture. As such, there may be a portion of bare metal at one or more edges of the display remaining from the manufacturing process of the panel itself. For instance, frame structure 19 may also be referred to as an LCD metal bezel (not to be confused with an LCD bezel that fits over the completed touch-enabled display). Thus, frame structure 19 may partially cover a front of the LCD sandwich and it should be understood that front face 18A may be defined by the LCD components and/or frame structure 19. Similarly, one or more edges 18B, 18T may be defined at least in part by frame structure 19.

In any event, mounting assembly 10 can be placed directly on the front face 18A of panel 18, without the use of glass, plastic, or another transparent cover material. As shown in FIG. 3, mounting assembly 10 also serves to cover frame structure 19. This can also aid in providing a good appearance—typically frame structure 19 comprises metal and should be obscured from view so as not to detract from what is being displayed.

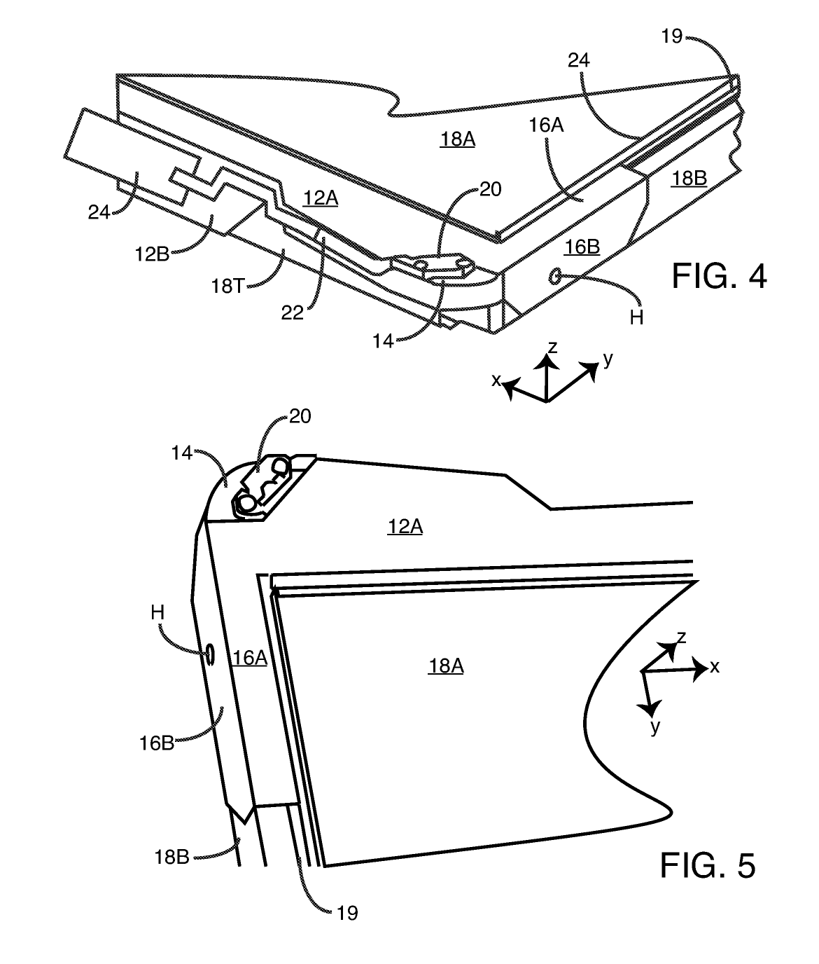

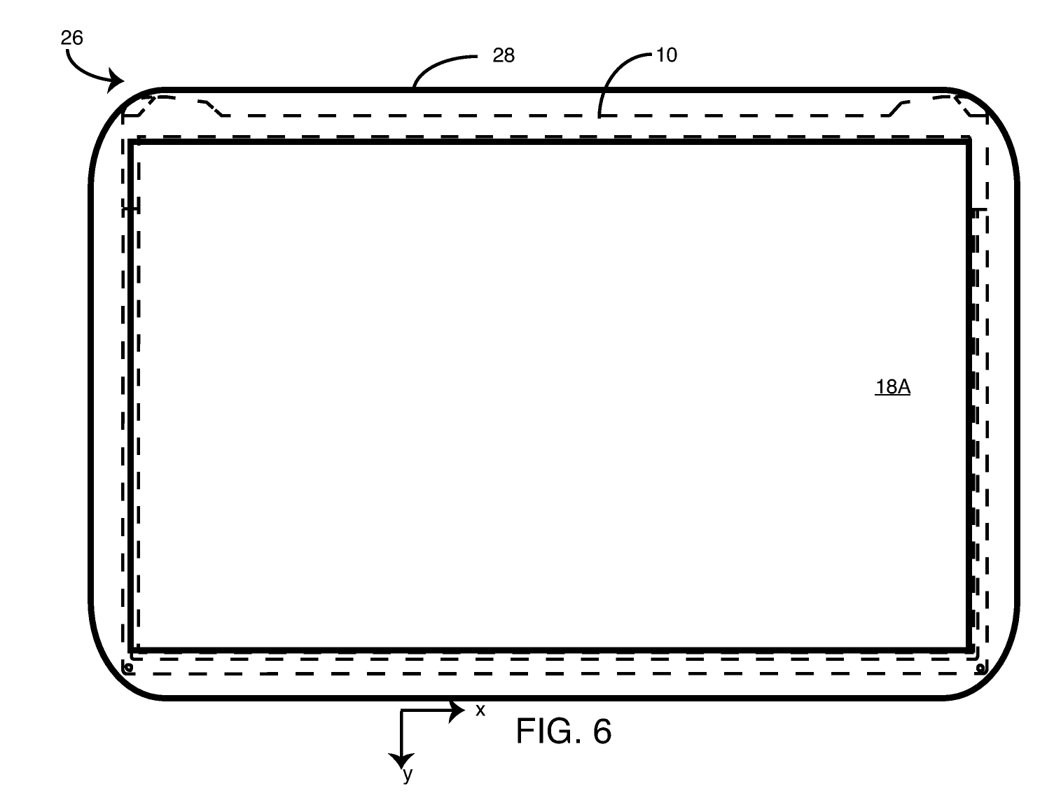

FIGS. 4-5 show placement of mounting assembly 10 onto panel 18 in closer detail. Mounting assembly 10 fits over side edge 18B and top edge 18T of panel 18, with the edges fitting snugly between faces 12A, 16A, 12B, and 16B. Although not shown here, faces 17A and 17B fit over edge 18B on the opposite side of panel 18 as well. As noted above, the faces can be joined or formed at 90 degree angles or another angle to ensure that engagement is close and accurate. Such a configuration minimizes the height of the bezel 28 (see FIG. 6) and enables touch detection in proximity to the display. One or more holes H may be included to attach mounting assembly 10 through the use of screws, pegs, or other fasteners. As another example, adhesive or another mechanism can be used.

Sensor receiving portion 14 is formed as a recessed area in this example and features a sensor 20 positioned therein. Although sensor receiving portion 14 is shown as a recessed area in this example, other embodiments need not include a recessed portion—another structure could be used, or a very low profile sensor could be used with a sensor receiving portion 14 that is coplanar with faces 12A/16A. Sensor 20 can comprise any suitable optical component(s) used in an optical touch system. For example, sensor 20 may comprise a line or area detector. In some implementations, sensor 20 is included in an optical unit featuring a sensor and an illumination source, such as one or more light emitting diodes used to emit infrared or other light.

A cable 22 connects sensor 20 to a printed circuit board 24. Circuit board 24 may contain a suitable processing device capable of processing signals from the sensor 20. As an example, circuit board 24 may include a digital signal processor or microcontroller. As another example, an external processor may be connected to the sensor 20 or the printed circuit board 24. Preferably however, all required processing is performed by a processor located on the sensor mounting member 10. An external cable, such as a USB cable may then be provided to connect mounting assembly to a computing device. Side face 12B may be adapted to receive circuit board 24, and may feature a recess, mounting points, or other structural aspects to hold circuit board 24 and cable 22 in place.

In these examples, sensor receiving portion 14 is formed as a recess in a flared portion at the junction between elongated member 12 and mounting portions 16 and 17. The flared portion may, for example, be attached to a metal or other member defining elongated member 12 and portions 16, 17. However, other configurations are possible. For instance, sensor receiving portion 14 may be formed integrally with elongated member 12 and/or mounting portions 16, 17.

In one embodiment, mounting assembly 10 comprises a sheet metal part formed to define faces 12A, 12B, 16A, 16B, 17A, and 17B in a configuration as shown here. The sheet metal can be approximately 0.40 mm thick, with overall dimensions of 496.2 mm×59 mm×12.5 mm deep (in the x, y, and z dimensions, respectively, as shown). Of course, other sizes could be used to accommodate different display heights, widths, and/or thicknesses. Additionally, mounting assembly 10 can be assembled from any suitable material, and rather than being formed as a unitary member could be assembled from any number of separate components. Still further, in some embodiments, elongated member 12 is extendible. For example, elongated member 12 could be formed as a telescopic member to be extended or compressed along the first direction (i.e., along the x-axis). Additionally or alternatively, members 16 and 17 could be configured as telescoping.

An optical touch sensitive display can be manufactured by placing mounting assembly across an edge of a display 18 so as to cover a bare metal or other exposed portion 19 of the display 18. Two sensors 20 are placed in sensor receiving portions 14 so as to view the area directly adjacent the surface of the display 18. The sensors 20 can be used to sense any object within their field of view and the processor or processors of circuit board 24 can calculate the location of the object based on triangulation.

In this manner, a touch upon the surface of the display 18 may be detected and the position determined. For example, as noted above one or more light sources can be provided on or near the sensors 20. These light sources may emit light which illuminates the area adjacent the display 18. An interruption of this light may be detected by the sensors 20. A retroreflective border 24 around the display 18 may assist in this light proliferation by reflecting light back towards its source in the absence of an interruption by an object.

As another example, a sensor may be mounted at a first sensor receiving portion 14 with another optical component (e.g., a light source) mounted at another receiving portion 14, with another technique used to determine the location of an object.

In this example, the mounting assembly is positioned along a top edge. It will be understood that other arrangements can be used, and thus any edge of panel 18 could be the “top edge” for purposes of the present subject matter. Additionally, a second mounting assembly 10 could be used at an edge of panel 18 opposite the top edge 18T.

FIG. 6 shows a completed touch-enabled display apparatus 26. In this example, an LCD bezel 28 is positioned over mounting assembly 10, which is itself positioned over frame 19 of the actual LCD or other display components (all shown in dashed lines). As can be seen here, LCD bezel 28 defines an outward appearance of the display 26 and protects the optical components. The term “LCD” bezel 28 is used for purposes of this example—more generally, bezel 28 is meant to refer to a “display bezel” as the present subject matter is not limited to a particular display type or technology.

As discussed aboard, a mounting assembly 10 can accommodate processing elements, such as a processor and/or other hardware on circuit board 24. Other hardware elements can be integrated with mounting assembly 10 as well. For example, an antenna can be integrated with mounting assembly 10. In some implementations, a circuit board with suitable hardware for using the antenna could be carried by mounting assembly 10 as well.

As another example, sensor hardware and/or hardware for support of external sensors can be included in mounting assembly 10. For example, a webcam, microphone, or other sensor(s) can be included on mounting assembly 10, located at a suitable point so that when the mounting assembly is mounted to the panel with a display bezel located over the mounting assembly, the webcam or other sensor(s) are aligned with a suitable opening to the front of the completed device. Additionally or alternatively, mounting assembly 10 may include circuitry for a webcam, microphone, and/or other sensor, with the actual sensor included in or external to the display bezel. In such instances, the circuitry on/in mounting assembly 10 can be positioned at a suitable location to align with connections to the sensor or other hardware included in or external to the display bezel.

While the present subject matter has been described in detail with respect to specific embodiments thereof, it will be appreciated that those skilled in the art, upon attaining an understanding of the foregoing may readily produce alterations to, variations of, and equivalents to such embodiments. Accordingly, it should be understood that the present disclosure does not preclude inclusion of such modifications, variations and/or additions to the present subject matter as would be readily apparent to one of ordinary skill in the art upon review of this disclosure.

1. An apparatus comprising:
a display device defining a front face, a top edge perpendicular to the front face, and side edges perpendicular to the front face and the top edge;
a mounting assembly mounted to the display device; and
a device bezel located over the mounting assembly,
wherein the mounting assembly comprises:
an elongated member defining a top face extending in a plane, the elongated member extending in a first direction,
a first mounting portion extending perpendicular to a first end of the elongated member, and
a second mounting portion extending perpendicular to a second end of the elongated member,
wherein the elongated member further defines a first side face perpendicular to the top face,
wherein each of the plurality of mounting portions further defines a second side face perpendicular to the top face,
wherein the mounting assembly is mounted with the top face of the elongated member overlaying at least a portion of the front face of the display and the first side face overlaying at least a portion of the top edge,
wherein the mounting assembly is positioned with a top face of each mounting portion overlaying at least a portion of the front face of the display device and each of the second side faces overlaying at least a portion of a respective side edge of the display device and
wherein the device bezel is located over the mounting assembly so as to cover the top face of the elongated member.

2. The apparatus of claim 1, wherein the display device comprises an LCD display, the front face of the LCD display comprising the LCD or a cover over the LCD.

3. The apparatus of claim 1, wherein the mounting assembly further comprises:
a plurality of sensor receiving portions, each sensor receiving portion located at a junction between the elongated member and the mounting portion, each sensor receiving portion shaped to receive a sensor.

4. The apparatus of claim 3, wherein each sensor receiving portion defines a recess in the top face.

5. The apparatus of claim 3, further comprising a sensor positioned at at least one sensor receiving portion.

6. The apparatus of claim 3, further comprising a circuit board connected to the sensor and mounted to the first side face.

7. The apparatus of claim 1, wherein the elongated portion is extendible in the first direction.

8. An apparatus comprising:
a display device defining a front face, a top edge perpendicular to the front face, and side edges perpendicular to the front face and the top edge;
a mounting assembly mounted to the display device; and
a device bezel located over the mounting assembly,
wherein the mounting assembly comprises:
an elongated member defining a top face extending in a plane, the elongated member extending in a first direction,
a first mounting portion extending perpendicular to a first end of the elongated member, and
a second mounting portion extending perpendicular to a second end of the elongated member,
wherein the elongated member further defines a first side face perpendicular to the top face,
wherein each of the plurality of mounting portions further defines a second side face perpendicular to the top face,
wherein the mounting assembly is mounted with the top face of the elongated member overlaying at least a portion of the front face of the display and the first side face overlaying at least a portion of the top edge,
wherein the mounting assembly is positioned with a top face of each mounting portion overlaying at least a portion of the front face of the display device and each of the second side faces overlaying at least a portion of a respective side edge of the display device,
wherein the device bezel is located over the mounting assembly so as to cover the top face of the elongated member, and
wherein the mounting assembly further comprises a plurality of sensor receiving portions, each sensor receiving portion located at a junction between the elongated member and the mounting portion, each sensor receiving portion shaped to receive a sensor.

9. An apparatus comprising:
a display device defining a front face, a top edge perpendicular to the front face, and side edges perpendicular to the front face and the top edge;
a mounting assembly mounted to the display device; and
a device bezel located over the mounting assembly,
wherein the mounting assembly comprises:
an elongated member defining a top face extending in a plane, the elongated member extending in a first direction,
a first mounting portion extending perpendicular to a first end of the elongated member, and
a second mounting portion extending perpendicular to a second end of the elongated member,
wherein the elongated member further defines a first side face perpendicular to the top face,
wherein each of the plurality of mounting portions further defines a second side face perpendicular to the top face,
wherein the mounting assembly is mounted with the top face of the elongated member overlaying at least a portion of the front face of the display and the first side face overlaying at least a portion of the top edge,
wherein the mounting assembly is positioned with a top face of each mounting portion overlaying at least a portion of the front face of the display device and each of the second side faces overlaying at least a portion of a respective side edge of the display device,
wherein the device bezel is located over the mounting assembly so as to cover the top face of the elongated member,
wherein the mounting assembly further comprises a plurality of sensor receiving portions, each sensor receiving portion located at a junction between the elongated member and the mounting portion, each sensor receiving portion shaped to receive a sensor, and
wherein each sensor receiving portion defines a recess in the top face.
